(19) United States
(12) Patent Application Publication
(10) Pub. No.: US 2025/0226367 A1
(43) Pub. Date: Jul. 10, 2025

(54) DISPLAY PANEL, METHOD OF MANUFACTURING DISPLAY PANEL AND ELECTRONIC DEVICE

(71) Applicants: Hefei Visionox Technology Co., Ltd., Hefei (CN); Visionox Technology Inc., Suzhou (CN)

(72) Inventors: Xiaoxi SUN, Hefei (CN); Yuan YAO, Hefei (CN); Xuejing ZHU, Hefei (CN); Yongqiang DU, Hefei (CN); Bo RAO, Hefei (CN); Shizhen FENG, Hefei (CN)

(73) Assignees: Hefei Visionox Technology Co., Ltd., Hefei (CN); Visionox Technology Inc., Suzhou (CN)

(21) Appl. No.: 18/779,682

(22) Filed: Jul. 22, 2024

(30) Foreign Application Priority Data
Jan. 10, 2024 (CN) 202410038162.8

(51) Int. Cl. H01L 25/16; G06F 3/041; H01L 27/15

(52) U.S. Cl. CPC H01L 25/167; G06F 3/04164; H10H 29/142

(57) ABSTRACT

A display panel, a method of manufacturing the display panel and an electronic device The display panel includes a display region and a non-display region. The display panel includes a substrate; a first organic layer, located on a side of the substrate; an inorganic layer, located on a side of the first organic layer away from the substrate and provided with a via hole exposing at least a portion of the first organic layer and located within the first border region; and an isolation structure, located on a side of the inorganic layer away from the substrate and extending from the display region to the non-display region. An orthographic projection of the via hole on the substrate is located outside an orthographic projection of the isolation structure on the substrate.

### CROSS REFERENCE TO RELATED APPLICATION

This application claims a priority of Chinese Patent Application No. 202410038162.8, filed on Jan. 10, 2024, titled with “DISPLAY PANEL, METHOD OF MANUFACTURING DISPLAY PANEL AND ELECTRONIC DEVICE”, which is incorporated herein in its entirety.

### TECHNICAL FIELD

The present application relates to the technical field of display, and in particular to a display panel, a method of manufacturing the display panel and an electronic device.

### BACKGROUND

A flat display device based on the technical of Organic Light Emitting Diode (OLED), Light Emitting Diode (LED) or the like has the advantages such as high image quality, low power consumption, thin body and wide application range, thus is widely used in various consumer electronic products such as a mobile phone, a television, a laptop and a desktop computer, and becomes the mainstream in a display panel.

However, the reliability of the display panel in a related art is not good enough.

### SUMMARY

In order to overcome the technical problems in the background as mentioned above, embodiments in the present application provide a display panel, including a display region and a non-display region, the non-display region includes a first border region, and the display panel includes:
a substrate;
a first organic layer, located on a side of the substrate;
an inorganic layer, located on a side of the first organic layer away from the substrate, and provided with a via hole exposing at least a portion of the first organic layer and located within the first border region; and
an isolation structure, located on a side of the inorganic layer away from the substrate and extending from the display region to the non-display region, and an orthographic projection of the via hole on the substrate being located outside an orthographic projection of the isolation structure on the substrate.

In some optional embodiments, the inorganic layer is provided with a plurality of via holes;
optionally, the plurality of via holes are provided uniformly;
optionally, the orthographic projection of each of the via holes on the substrate is in shape of at least one of rhombus, circle or square;
optionally, the first border region includes a first border sub-region and a second border sub-region located on two sides of the display region, respectively, and arranged opposite to each other in a first direction;
optionally, the display panel further includes a scan line, and the first direction is a direction in which the scan line extends within the display region;
optionally, the non-display region further includes a second border region, the second border region includes a bonding region, and the first border region further includes a third border sub-region located on a side of the display region away from the second border region;
optionally, the second border region and the third border sub-region are arranged in a second direction;
optionally, the second direction intersects with the first direction; and
optionally, the second direction is perpendicular to the first direction.

Optionally, orthographic projections of the via holes on the substrate are located on a side of the orthographic projection of the isolation structure on the substrate away from the display region; and
optionally, the non-display region at least partially surrounds the display region.

In some optional embodiments, the display panel further includes a dam structure located within the non-display region, the non-display region further includes a shielding region, and the dam structure is located on a side of the shielding region away from the display region; and
optionally, a density of a portion of the via holes located within the shielding region is lower than a density of a portion of the via holes located within a region close to the dam structure.

Optionally, the via holes within the shielding region are arranged uniformly;
optionally, the via holes are arranged uniformly in a direction from a side of the shielding region close to the dam structure to the dam structure.

Optionally, the density of the via holes gradually increases in a direction from the shielding region to the dam structure.

In some optional embodiments, a diameter of each of the via holes located within the shielding region is smaller than a diameter of each of the via holes located within a region close to the dam structure;
optionally, diameters of the via holes gradually increase in a direction from the shielding region to the dam structure;
optionally, a distance between two adjacent via holes located within the shielding region is larger than a distance between two adjacent via holes within the region close to the dam structure;
optionally, distances between adjacent via holes gradually decrease in a direction from the shielding region to the dam structure;
optionally, a diameter of the orthographic projection of an end of each of the via holes close to the substrate on the substrate ranges from 10 μm to 20 μm, and
optionally, the distance between two adjacent via holes ranges from 3 μm to 10 μm.

In some optional embodiments, a shielding layer is arranged on a side of the inorganic layer close to the substrate and within the shielding region, the shielding layer includes a plurality of shielding lines, the display panel further includes a touch layer located on a side of the isolation structure away from the substrate, the touch layer includes a plurality of touch electrodes, and orthographic projections of the touch electrodes on the substrate at least partially overlap with orthographic projections of the shielding lines on the substrate.

In some optional embodiments, orthographic projections of the via holes on the substrate are located outside the orthographic projections of the shielding lines on the substrate; and
optionally, in the shielding region, the orthographic projection of each of the via holes is located between orthographic projections of two adjacent shielding lines on the substrate.

In some optional embodiments, the display panel includes a first metal layer, a second metal layer, a third metal layer and a fourth metal layer sequentially stacked in a direction away from the substrate, and the fourth metal layer includes the shielding layer;
optionally, the display panel further includes a second organic layer located on a side of the shielding layer close to the substrate;
optionally, the display panel further includes a first planarization layer located between the third metal layer and the fourth metal layer, and the second organic layer includes the first planarization layer; and
optionally, the display panel further includes a second planarization layer located on a side of the fourth metal layer away from the substrate, and the first organic layer includes the second planarization layer.

In some optional embodiments, the display panel includes a first metal layer, a second metal layer, a third metal layer, a fourth metal layer, and a first electrode layer sequentially arranged in a direction away from the substrate, wherein the first electrode layer includes the shielding layer;
optionally, the first electrode layer is located between the first organic layer and the inorganic layer;
optionally, the first electrode layer includes a first electrode, and the first electrode includes an anode.

In some optional embodiments, the non-display region further includes a driving circuit region located between the display region and the shielding region, and the driving circuit region is provided with a driving circuit line; and
optionally, the driving circuit line includes a scanning control line and a light-emitting control line.

In some optional embodiments, the display panel further includes a first electrode layer, a light-emitting layer and a second electrode layer sequentially stacked in a direction away from the substrate, the first electrode layer includes a first electrode, the second electrode layer includes a second electrode, the isolation structure is provided with an isolation opening, the isolation opening is located within the display region, and the second electrode is located within the isolation opening and electrically connected to the isolation structure;
optionally, in the display region, an orthographic projection of the isolation structure on the substrate is in a mesh-shaped structure; and
optionally, the light-emitting layer includes a light-emitting part, that is located within the isolation opening.

Optionally, the display panel further includes a pixel-defining layer located on a side of the first electrode layer away from the substrate, the pixel-defining layer includes pixel openings that expose the first electrode, the orthographic projection of the isolation structure on the substrate is located between orthographic projections of two adjacent pixel openings on the substrate, and orthographic projections of the pixel openings on the substrate are located within a orthographic projection of the isolation opening on the substrate; and
optionally, the inorganic layer includes the pixel-defining layer.

In some optional embodiments, the display panel further includes a first inorganic encapsulation layer located on a side of the second electrode layer away from the substrate, and the first inorganic encapsulation layer includes a plurality of encapsulation units, that extend from a side face of the isolation structure onto a side of the isolation structure away from the substrate;
optionally, the display panel further includes an organic encapsulation layer located on a side of the first inorganic encapsulation layer away from the substrate, and the organic encapsulation layer extends from the display region to the non-display region and fills the via holes; and
optionally, the display panel further includes a second inorganic encapsulation layer located on a side of the organic encapsulation layer away from the substrate, and the second inorganic encapsulation layer extends from the display region to the non-display region.

In some optional embodiments, the isolation structure includes a first isolation portion and a second isolation portion sequentially stacked in the direction away from the substrate, and an orthographic projection of the first isolation portion is located within an orthographic projection of the second isolation portion on the substrate.

In some optional embodiments, the second electrode is electrically connected to the first isolation portion; and/or the isolation structure further includes a third isolation portion located on a side of the first isolation portion facing the substrate, and the second electrode is electrically connected to the third isolation portion; and
optionally, a material of the third isolation portion includes molybdenum metal; and/or a material of the first isolation portion includes aluminum metal; and/or a material of the second isolation portion includes titanium metal.

In some optional embodiments, the present application further provides a method for manufacturing a display panel, the display panel includes a display region and a non-display region, the non-display region includes a first border region, and the method includes: providing a substrate;
forming a first organic layer on a side of the substrate;
forming an inorganic layer on a side of the first organic layer away from the substrate, and providing a via hole, that exposes at least a portion of the first organic layer and is located within the first border region, on the inorganic layer; and
forming a isolation structure on a side of the inorganic layer away from the substrate, wherein the isolation structure extends from the display region to the non-display region, and an orthographic projection of the via hole on the substrate is located outside an orthographic projection of the isolation structure on the substrate.

In some optional embodiments, the present application further provides an electronic device, including the display panel as described in the present application.

Compared with a related art, the present application has the following beneficial effects:

The present application provides the display panel, the method of manufacturing the display panel and the electronic device. By providing the via hole, that exposes at least a portion of the first organic layer, on the inorganic layer, a path of discharging the gas inside a screen body can be provided on the inorganic layer, which can facilitate discharging the gas inside the screen body, and improve the reliability of the display panel.

### BRIEF DESCRIPTION OF THE DRAWINGS

In order to more clearly illustrate the technical solution of the embodiments of the present application, the drawings required to be used in the embodiments of the present application will be briefly introduced below. It should be understood that the following drawings merely illustrate some embodiments of the present application, and therefore should not be regarded as limiting the scope. For those skilled in the art, other drawings can also be obtained according to these drawings without the inventive labor.

FIG. 1 shows a cross-sectional schematic view of a display panel in a related art;

FIG. 2 shows a cross-sectional schematic view of a display panel according to an embodiment of the present application;

FIG. 3 shows a cross-sectional schematic view of a display panel including a shielding layer according to an embodiment of the present application;

FIG. 4 shows a top schematic view of a display panel according to an embodiment of the present application;

FIG. 5 shows a top schematic view of via holes on a substrate according to an embodiment of the present application;

FIG. 6 shows a top schematic view of via holes on a substrate according to another embodiment of the present application;

FIG. 7 shows a top schematic view of via holes on a substrate according to another embodiment of the present application;

FIG. 8 shows a cross-sectional schematic view of a shielding layer located on a fourth metal layer according to an embodiment of the present application;

FIG. 9 shows a cross-sectional schematic view of a display region of a display panel including four metal layers according to an embodiment of the present application;

FIG. 10 shows a cross-sectional schematic view of a shielding layer located on an anode layer according to an embodiment of the present application;

FIG. 11 shows a cross-sectional schematic view of a display region of a display panel including an anode layer according to an embodiment of the present application;

FIG. 12 shows a cross-sectional schematic view of a display region when an isolation structure separates a second electrode layer according to an embodiment of the present application;

FIG. 13 shows a top schematic view of an isolation structure in which an orthographic projection thereof on the substrate is in a mesh-shaped structure according to an embodiment of the present application;

FIG. 14 shows a cross-sectional schematic view of a display region when an isolation structure separates a first inorganic encapsulation layer according to an embodiment of the present application;

FIG. 15 shows a cross-sectional schematic view of a display region when a display panel includes an organic encapsulation layer according to an embodiment of the present application;

FIG. 16 shows a cross-sectional schematic view of an organic encapsulation layer extending to a non-display region according to an embodiment of the present application;

FIG. 17 shows a cross-sectional schematic view of a display region when a display panel includes a second inorganic encapsulation layer according to an embodiment of the present application;

FIG. 18 shows a cross-sectional schematic view of a second inorganic encapsulation layer extending to the non-display region according to an embodiment of the present application;

FIG. 19 shows a cross-sectional schematic view of an isolation structure including a structure with three layers according to an embodiment of the present application;

FIG. 20 shows a flow diagram of a method of manufacturing a display panel according to an embodiment of the present application;

FIG. 21 shows a cross-sectional schematic view of an organic layer formed on a side of a substrate according to an embodiment of the present application; and

FIG. 22 shows a cross-sectional schematic view of an inorganic layer formed on a side of an organic layer away from a substrate and provided with via holes according to an embodiment of the present application.

Reference numerals: 1. substrate; 2. first organic layer; 3. inorganic layer; 31. via hole; 4. isolation structure; 41. first isolation portion; 42. second isolation portion; 43. third isolation portion; 5. shielding layer; 51. shielding line; 6. touch layer; 61. touch electrode; 7. dam structure; 8. first metal layer; 81. gate; 82. first capacitive electrode plate; 9. second metal layer; 91. second capacitive electrode plate; 10. third metal layer; 101. source; 102. drain; 11. fourth metal layer; 12. second organic layer; 13. first planarization layer; 14. second planarization layer; 15. first electrode layer; 151. first electrode; 16. pixel-defining layer; 17. isolation opening; 18. light-emitting layer; 19. second electrode; 20. pixel opening; 21. first inorganic encapsulation layer; 211. encapsulation unit; 22. organic encapsulation layer; 23. second inorganic encapsulation layer; 24. scan line; 25. first border region; 251. first border sub-region; 252. third border sub-region; 253. second border sub-region; 26. second border region; 261. bonding region.

### DETAILED DESCRIPTION

In order to make the objects, the technical solutions and the advantages in embodiments of the present application clearer, the technical solutions in the embodiments of the present application will be described clearly and completely in conjunction with the drawings. Obviously, the embodiments as described below are a portion of the embodiments of the present application, not all of the embodiments. Generally, components in the embodiments of the present application described and shown in the drawings may be arranged and designed in various different configurations.

Therefore, the following detailed description in the embodiments of the present application provided in the drawings is not intended to limit the scope of the present application, but only to represent the optional embodiments of the present application. Based on the embodiments of the present application, all other embodiments obtained by those skilled in the art without the creative labor fall within the scope of the present application.

It should be noted that similar numerals and letters in the drawings below represent similar terms, therefore, once some numeral or letter is defined in a drawing, it does not need to be further defined or explained in other drawings.

In the description of the present application, it should be noted that the terms “center”, “up”, “down”, “vertical”, “horizontal”, “inside”, “outside” or the like indicate the orientations or position relationships based on the orientations or position relationships shown in the drawings, or the orientations or position relationships habitually placed when the invention product is used, are merely for the convenience of describing the present application and simplifying the description, rather than indicating or implying that the related devices or components must have specific orientations or must be constructed and operated in specific orientations, and therefore cannot be understood as the limitation of the present application. In addition, the terms “first”, “second”, “third” or the like are only used to distinguish the terms and cannot be understood as indicating or implying the relative importance.

It should be noted that, without conflict, different features in the embodiments of the present application can be combined with one another.

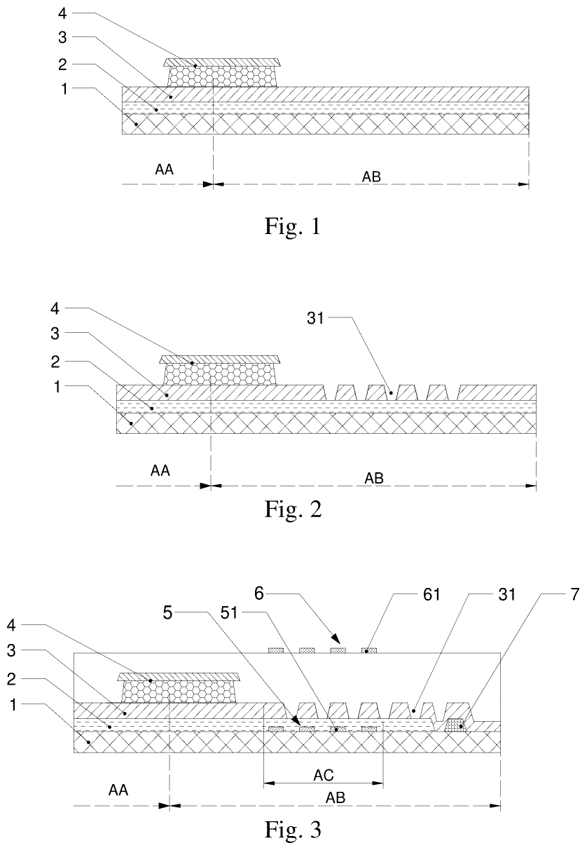

Referring to FIG. 1, the display panel in a related art includes a display region AA and a non-display region AB. The display panel further includes a substrate 1, a first organic layer 2 located on a side of the substrate 1, an inorganic layer 3 located on a side of the first organic layer 2 away from the substrate 1, and an isolation structure 4 located on a side of the inorganic layer 3 away from the substrate 1. The isolation structure 4 includes a conductive material, and the isolation structure 4 is electrically connected to a cathode within the display region AA of the display panel.

In a process of manufacturing the display panel, gas is generated in a film layer, which can be transferred between the organic layers but is difficult to transfer in inorganic layer 3. Since the inorganic layer 3 is arranged on a side of the isolation structure 4 close to the substrate 1, the gas on a side of the inorganic layer 3 close to the substrate 1 cannot be discharged through the inorganic layer 3. After the reliability testing, the encapsulation failure is easy to occur, and the reliability of the display panel is reduced.

In view of this, the embodiment provides a solution that can improve the reliability of the display panel. The solution provided by the embodiment will be illustrated in detail below.

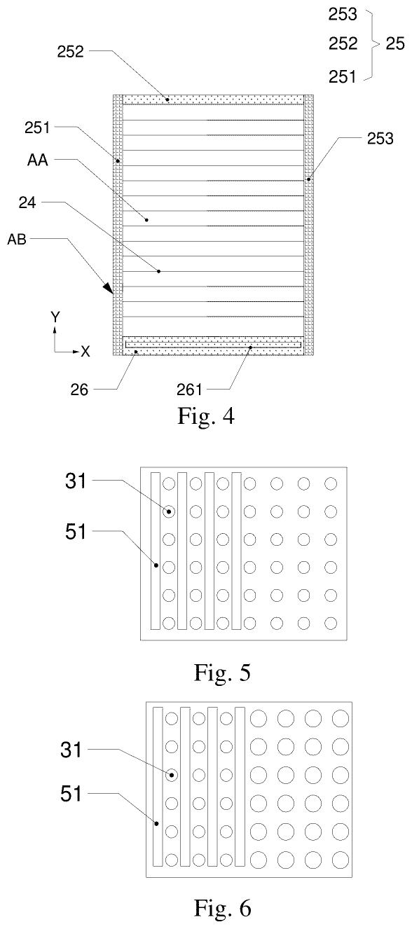

Referring to FIG. 2 and FIG. 4, embodiments of the present application provide a display panel including a display region AA and a non-display region AB. The non-display region AB includes a first border region 25, and the display panel includes a substrate 1, a first organic layer 2, an inorganic layer 3 and an isolation structure 4.

The first organic layer 2 is located on a side of the substrate 1. The inorganic layer 3 is located on a side of the first organic layer 2 away from the substrate 1. The inorganic layer 3 is provided with a via hole 31 exposing at least a portion of the first organic layer 2. The via hole 31 is located within the first border region 25. The isolation structure 4 is located on a side of the inorganic layer 3 away from the substrate 1 and extends from the display region AA to the non-display region AB. An orthographic projection of the via hole 31 on the substrate 1 is located outside an orthographic projection of the isolation structure 4 on the substrate 1.

The gas generated in the film layer of the screen can be transferred in the first organic layer 2 and reach to the via holes 31. Since the orthographic projections of the via holes 31 on the substrate 1 are located outside the orthographic projection of the isolation structure 4 on the substrate 1, the isolation structure 4 cannot block the gas from being discharged through the via holes 31. Thus, the display panel has the path of discharging the gas, so that it is easier to discharge the gas inside the screen body. After the reliability testing, the encapsulation failure is not easy to occur, and the reliability of the display panel can be improved.

Based on the above design, in the present application, by providing the via holes 31, that exposes at least a portion of the first organic layer 2, on the inorganic layer 3, the path of discharging the gas inside the screen body can be arranged on the inorganic layer 3, which can facilitate discharging the gas inside the screen body, and improve the reliability of the display panel.

In some optional embodiments, referring to FIG. 3, the display panel further includes a dam structure 7 located within the non-display region AB, the non-display region AB further includes a shielding region AC, and the dam structure 7 is located on a side of the shielding region AC away from the display region AA. A shielding layer 5 is arranged on a side of the inorganic layer 3 close to the substrate 1 and within the shielding region AC. The shielding layer 5 includes a plurality of shielding lines 51, the display panel further includes a touch layer 6 located on a side of the isolation structure 4 away from the substrate 1. The touch layer 6 includes a plurality of touch electrodes 61. Orthographic projections of the touch electrodes 61 on the substrate 1 at least partially overlap with orthographic projections of the shielding lines 51 on the substrate 1.

The touch electrodes 61 are arranged on a side of the shielding layer 5 away from the substrate 1, and a signal line with voltage jump, such as a data signal line or a control signal line, is arranged on a side of the shielding layer 5 close to the substrate 1. The voltage jump of the signal line may affect the touch accuracy of the touch electrodes 61. The shielding layer 5 includes the shielding line 51, and the voltage of the shielding line 51 is not prone to jumping. For example, the shielding line 51 can be used to transfer driving voltage (VDD), common voltage (VSS), reset voltage (Vref) or the like. Thus, the shielding layer 5 is arranged between the touch electrodes 61 and the signal line, and the voltage of the shielding line 51 of the shielding layer 5 is not easy to jump, thereby improving the touch accuracy of the touch electrodes 61.

In some optional embodiments, referring to FIG. 3 again, there are a plurality of via holes 31. Thus, there are a plurality of paths for discharging gas inside the screen body, which can further increase the spillage amount of the gas inside the screen body and further solve the problem of the encapsulation failure of the display panel.

Optionally, referring to FIG. 3 again, the via holes 31 are located within the non-display region AB, so that the paths of discharging the gas can be arranged within the non-display region AB and cannot affect the display effect of the display region AA.

Furthermore, the orthographic projections of the via holes 31 on the substrate 1 are located on a side of the orthographic projection of the isolation structure 4 on the substrate 1 away from the display region AA. The isolation structure 4 may not extend to a side of the via holes 31 away from the substrate 1, so that the isolation structure 4 cannot block the gas from being discharged through the via holes 31, and can facilitate discharging the gas.

Optionally, referring to FIG. 4 again, the non-display region AB at least partially surrounds the display region AA. The first border region 25 includes a first border sub-region 251 and a second border sub-region 253 located on two sides of the display region AA, respectively, and arranged opposite to each other in a first direction X. The display panel further includes a scan line 24, and the first direction X is a direction in which the scan line extends within the display region AA. The non-display region AB further includes a second border region 26, the second border region 26 includes a bonding region 261, and the first border region 25 further includes a third border sub-region 252 located on a side of the display region AA away from the second border region 26. The second border region 26 and the third border sub-region 252 are arranged in a second direction Y. The second direction Y intersects with the first direction X, and optionally, the second direction Y is perpendicular to the first direction X.

The bonding region 261 can bond a circuit board. The second border region 26 is a lower border of the display panel, the first border sub-region 251 and the second border sub-region 253 are a left border and a right border of the display panel, respectively, and the third border sub-region 252 is an upper border of the display panel. Thus, the via holes 31 can be provided on the upper border, the left border and the right border of the display panel, and the gas inside the screen can be discharged from the upper border, the left border and the right border of the display panel.

Optionally, the orthographic projection of each of the via holes 31 on the substrate 1 is in shape of at least one of rhombus, circle or square. The via holes 31 can be set to different shapes according to actual needs, which is not limited here.

In some optional embodiments, orthographic projections of the via holes 31 on the substrate 1 are located outside the orthographic projections of the shielding lines 51 on the substrate 1.

If the orthographic projections of via hole 31 on substrate 1 coincide with the orthographic projections of the shielding lines 51 on the substrate 1, the gas in the film layer on a side of shielding line 51 close to substrate 1 may be blocked by the shielding lines 51 and not easy to reach the via holes 31, so that it is difficult to discharge the gas inside the screen body through via holes 31.

In this embodiment, the orthographic projections of the via holes 31 on substrate 1 do not coincide with the orthographic projections of shielding lines 51 on substrate 1. The shielding lines 51 are not easy to block the gas on the side of the shielding lines 51 close to the substrate 1 from reaching the via holes 31, so that it is easier to discharge the gas inside the screen body, and the reliability of the display panel can be further improved.

In some optional embodiments, referring to FIG. 3 and FIG. 5, in the shielding region AC, the orthographic projection of each of the via holes 31 on the substrate 1 is located between orthographic projections of two adjacent shielding lines 51 on the substrate 1. The gas located on a side of shielding lines 51 close to the substrate 1 can reach the via holes 31 through a gap between the shielding lines 51, and then be discharged through the via holes 31.

The plurality of via holes 31 can be differentiated.

In some embodiments, referring to FIG. 5 again, the plurality of via holes 31 are provided uniformly. Thus, the shapes, the sizes, the distances or the like of all via holes 31 can be the same, so as to facilitate arranging the via holes 31 and reduce the cost of arranging the via holes 31.

In some other embodiments, referring to FIG. 6, the via holes 31 within the shielding region AC are provided uniformly, the via holes 31 in a direction from a side of the shielding region AC close to the dam structure 7 to the dam structure 7 are provided uniformly, and a density of a portion of the via holes 31 located within the shielding region AC is lower than a density of a portion of the via holes 31 located within a region close to the dam structure 7.

Since the shielding lines 51 are arranged within the shielding region AC, the orthographic projections of the via holes 31 on the substrate 1 are located outside the orthographic projections of the shielding lines 51 on the substrate 1. Therefore, the density of a portion of the via holes 31 within the shielding region AC is lower than the density of a portion of the via holes 31 located within the region close to the dam structure 7, so that the number of the paths of discharging the gas can increase. The sizes and the distances of the via holes 31 within the shielding region AC are the same, and the sizes and the distances of the via holes 31 from the side of the shielding region AC close to the dam structure 7 to the dam structure 7 are the same, so that it is easier to set the corresponding via holes 31.

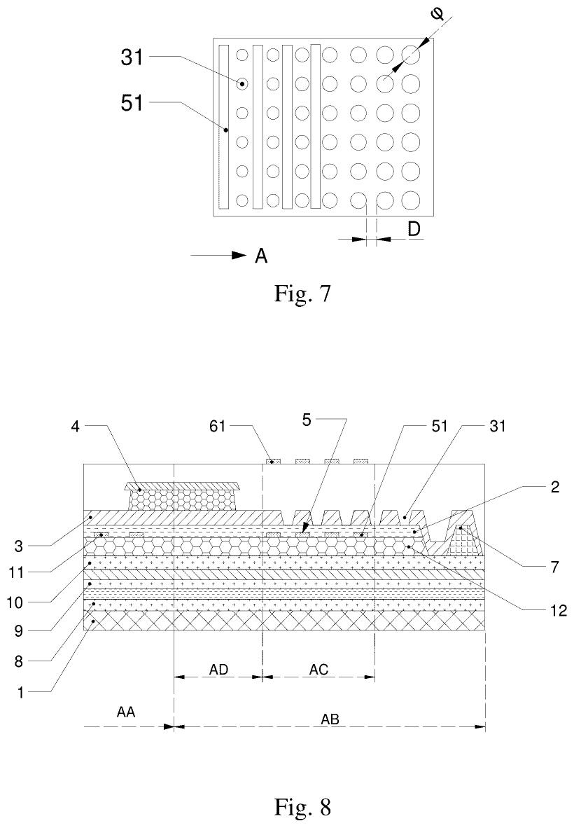

In some other embodiments, referring to FIG. 7, the density of a portion of the via holes 31 located within the shielding region AC is lower than the density of a portion of the via holes 31 located within the region close to the dam structure 7, and the density of the via holes 31 gradually increases in a direction A from the shielding region AC to the dam structure 7.

Specifically, a diameter of each of the via holes 31 located within the shielding region AC is smaller than a diameter of each of the via holes 31 located within the region close to the dam structure 7.

Further, diameters of the via holes 31 gradually increase in the direction A from the shielding region AC to the dam structure 7.

Specifically, a distance between two adjacent via holes 31 located within the shielding region AC is larger than a distance between two adjacent via holes 31 within the region close to the dam structure 7.

Further, distances between adjacent via holes 31 gradually decrease in the direction A from the shielding region AC to the dam structure 7.

In this embodiment, in the non-display region AB, by arranging the shielding lines 51 within the shielding region AC, the via holes 31 can be further differentiated, so that more via holes 31 can be provided within the non-display region AB, which can further increase the number of the paths of discharging the gas inside the screen body and ultimately improve the effect of discharging the gas inside the screen body.

Optionally, referring to FIG. 7, a diameter φ of the orthographic projection of an end of each of the via holes 31 close to the substrate 1 on the substrate 1 ranges from 10 μm to 20 μm. For example, the diameter may be 10 μm, 12 μm, 15 μm, 18 μm or 20 μm. By reasonably setting the diameter φ, more paths of discharging the gas within the non-display region AB can be arranged, thereby improving the gas-discharging effect inside the screen body.

Optionally, referring to FIG. 7, the distance D between two adjacent via holes 31 ranges from 3 μm to 10 μm. For example, the distance D may be 3 μm, 5 μm, 8 μm or 10 μm. By reasonably setting the distance D, more paths of discharging the gas within the non-display region AB can be arranged, thereby improving the gas-discharging effect inside the screen body.

In some optional embodiments, referring to FIG. 8, the display panel includes a first metal layer 8, a second metal layer 9, a third metal layer 10 and a fourth metal layer 11 sequentially stacked in a direction away from the substrate 1, and the fourth metal layer 11 includes the shielding layer 5. The display panel further includes a second organic layer 12 located on the side of the shielding layer 5 close to the substrate 1.

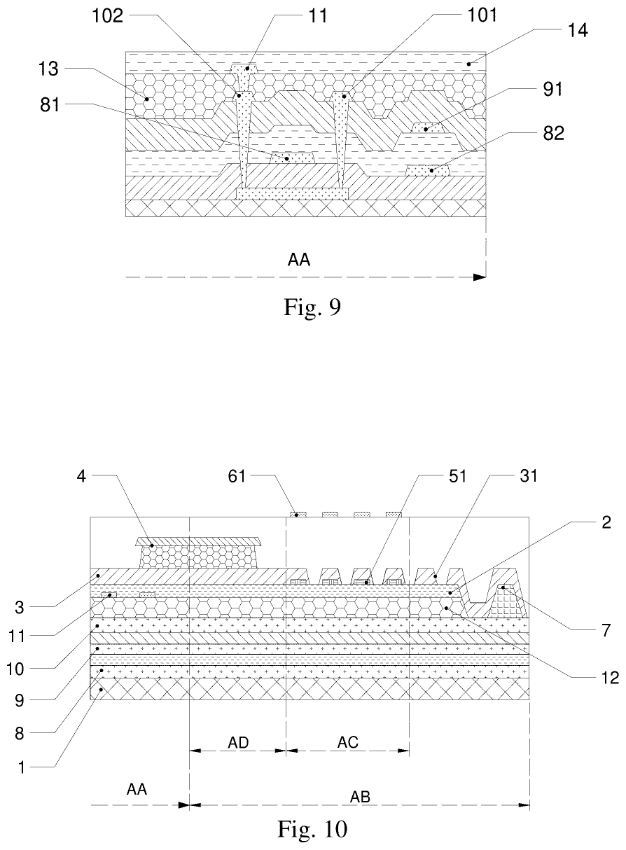

Referring to FIG. 9, in the display region AA of the display panel, the display panel further includes a semiconductor layer, which includes a source region, a drain region and a groove region. The first metal layer 8 includes a gate 81 and a first capacitive electrode plate 82. The second metal layer 9 includes a second capacitive electrode plate 91. The first capacitive electrode plate 82 and the second capacitive electrode plate 91 form a capacitor. The third metal layer 10 includes a drain 102 and a source 101. The drain 102 is electrically connected to the drain region. The source 101 is electrically connected to the source region. The gate 81, the source 101 and the drain 102 form a switching device. The fourth metal layer 11 includes a metal line. The drain 102 is connected to the metal line.

In the non-display region AB of the display panel, the shielding layer 5 corresponds to the fourth metal layer 11, the metal line in the fourth metal layer 11 includes the shielding lines 51. The shielding layer 5 can shield the affect of the signal line on a side of the fourth metal layer 11 close to the substrate 1 on the touch electrodes 61 in the touch layer 6.

In some optional embodiments, referring to FIG. 8 again, the non-display region AB further includes a driving circuit region AD located between the display region AA and the shielding region AC, and the driving circuit region AD is provided with a driving circuit line. For example, the driving circuit line includes a scanning control line and a light-emitting control line. The scanning control line and the light-emitting control line can control a light-emitting sub-pixel within the display region AA to emit the light.

Optionally, referring to FIG. 9 again, in the display region AA, the display panel further includes a first planarization layer 13 located between the third metal layer 10 and the fourth metal layer 11, and the second organic layer 12 includes the first planarization layer 13.

Referring to FIG. 8 again, the first planarization layer 13 extends from the display region AA to the non-display region AB, and the second organic layer 12 is the first planarization layer 13. The gas in the film layer of the screen body can reach the first organic layer 2 from the first planarization layer 13, then reach the via holes 31 from the first organic layer 2, and be discharged from the via holes 31. Thus, the first planarization layer 13 within the display region AA can be used as the second organic layer 12, without the need to specifically arrange the second organic layer 12 within the non-display region AB, thereby reducing the cost of specifically arranging the second organic layer 12.

Optionally, referring to FIG. 9 again, in the display region AA, the display panel further includes a second planarization layer 14 located on a side of the fourth metal layer 11 away from the substrate 1, and the first organic layer 2 includes the second planarization layer 14.

Referring to FIG. 8 again, the second planarization layer 14 extends from the display region AA to the non-display region AB, and the first organic layer 2 is the second planarization layer 14. The gas flows from the second planarization layer 14 to the via holes 31 and is then discharged from the via holes 31. Thus, the second planarization layer 14 within the display region AA can be used as the first organic layer 2, without the need to specifically arrange the first organic layer 2 within the non-display region AB, thereby reducing the cost of specifically arranging the first organic layer 2.

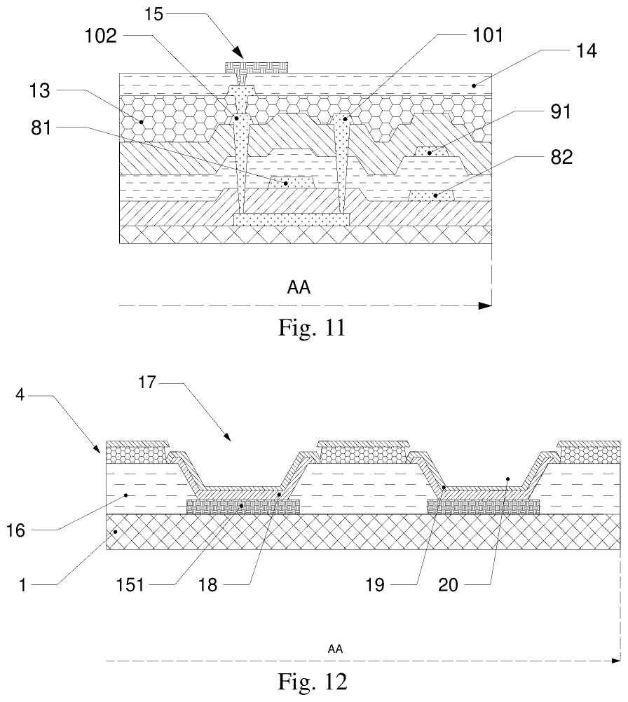

In some optional embodiments, referring to FIG. 10 and FIG. 11, the display panel includes a first metal layer 8, a second metal layer 9, a third metal layer 10, a fourth metal layer 11 and a first electrode layer 15 sequentially arranged in a direction away from the substrate 1, the first electrode layer 15 includes the shielding layer 5, and the first electrode layer 15 is located between the first organic layer 2 and the inorganic layer 3.

In the non-display region AB, conductive lines of the first electrode layer 15 can be used as the shielding lines 51. Thus, the conductive lines of the first electrode layer 15 can be used to shield a touch line of the touch layer 6 and the signal line located on the side of the shielding layer 5 close to the substrate 1, without the need to specifically arrange the shielding layer 5 within the non-display region AB, thereby reducing the cost of specifically arranging the shielding layer 5.

In some optional embodiments, referring to FIG. 12, in the display region AA, the display panel further includes a pixel-defining layer 16 located on a side of the first electrode layer 15 away from the substrate 1. The pixel-defining layer 16 includes pixel openings 20 that expose a first electrode 151. The isolation structure 4 is located on a side of the pixel-defining layer 16 away from substrate 1. The first electrode layer 15 includes a plurality of first electrodes 151 spaced apart from one another. The first electrodes 151 are anodes. The orthographic projection of the isolation structure 4 on the substrate 1 is located between orthographic projections of two adjacent pixel openings 20 on the substrate 1, and orthographic projections of the pixel openings 20 on the substrate 1 are located within an orthographic projection of an isolation opening 17 on the substrate 1.

The display panel further includes a light-emitting layer 18 and a second electrode layer located in the first electrode layer 15 and sequentially stacked in a direction away from the substrate 1. The second electrode layer includes a second electrode 19. The second electrode 19 is a cathode. The light-emitting layer 18 includes a light-emitting part. The isolation structure 4 is provided with the isolation opening 17, which is located within the display region AA. The second electrode 19 is located within the isolation opening 17 and electrically connected to the isolation structure 4. Both the light-emitting part and the second electrode 19 are located within the isolation opening 17. The first electrode 151, the light-emitting part and the second electrode 19 form the light-emitting sub-pixel, which may be a red sub-pixel, a green sub-pixel or a blue sub-pixel.

When the second electrode layer is formed, the isolation structure 4 can separate the second electrode layer to form a plurality of second electrodes 19 which are spaced apart from one another. At least a portion of the second electrodes 19 extend from the pixel opening 20 to the side of the pixel-defining layer 16 away from the substrate 1 and are in electrical contact with the isolation structure 4.

Optionally, the inorganic layer 3 includes the pixel-defining layer 16, which extends from the display region AA to the non-display region AB, and is provided with the via holes 31 within the non-display region AB. Thus, there is no need to specifically provide the inorganic layer 3, so that the cost of providing the inorganic layer 3 can be reduced.

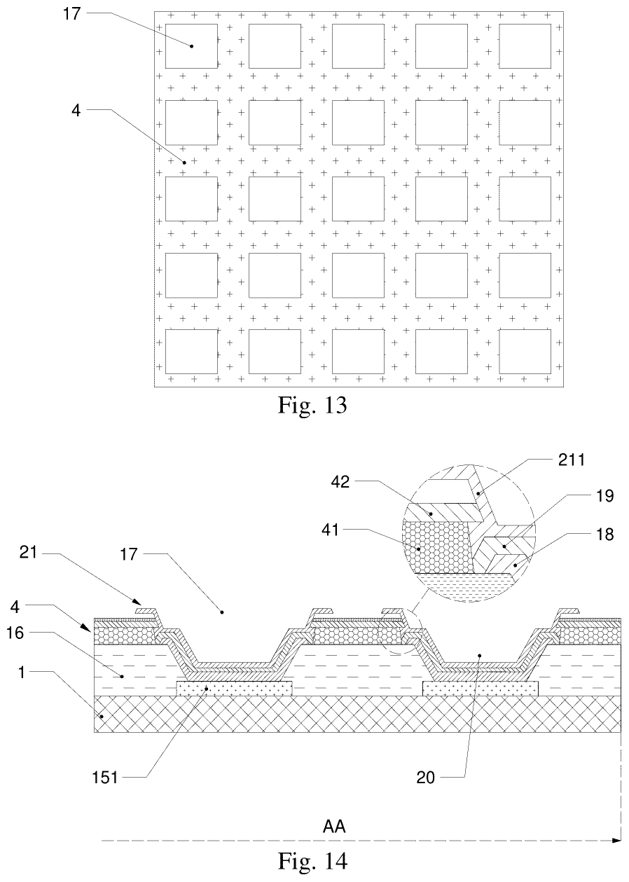

Optionally, referring to FIG. 13, in the display region AA, an orthographic projection of the isolation structure 4 on the substrate 1 is in a mesh-shaped structure. Thus, the isolation structure 4 can better separate the second electrode layer to form the plurality of second electrodes 19 spaced apart from one another and located within the isolation opening 17.

In some optional embodiments, referring to FIG. 14, the display panel further includes a first inorganic encapsulation layer 21 located on a side of the second electrode layer away from the substrate 1, and the first inorganic encapsulation layer 21 includes a plurality of encapsulation units 211, that extend from a side face of the isolation structure 4 onto a side of the isolation structure 4 away from the substrate 1.

The isolation structure 4 includes a side close to the substrate 1, a side away from the substrate 1 and a side face. The adjacent encapsulation units 211 are spaced apart from one another on the side of the isolation structure 4 away from the substrate. The encapsulation units 211 independently package a plurality of light-emitting sub-pixels, respectively, so that the plurality of light-emitting sub-pixels are independent to one another, so as to improve the reliability of the encapsulation and optimize the optical performance of the display panel.

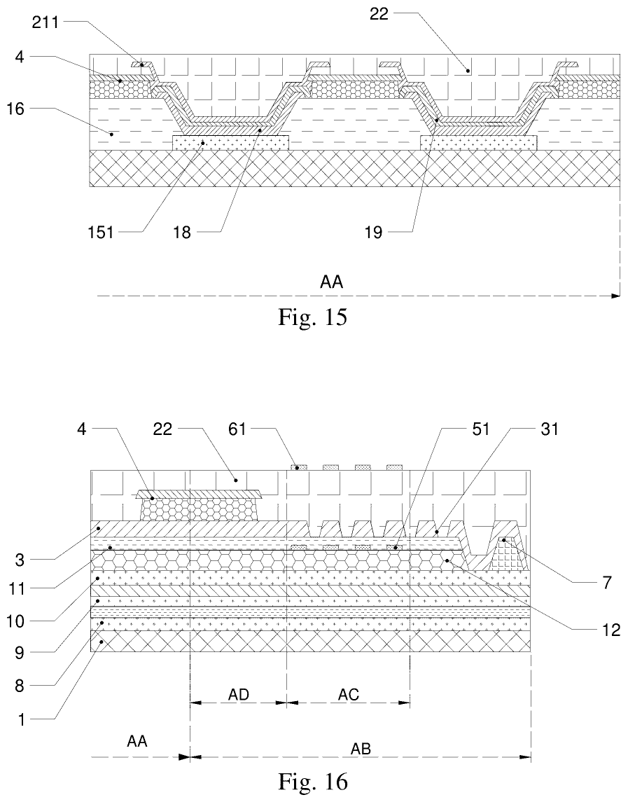

Optionally, referring to FIG. 15 and FIG. 16, the display panel further includes an organic encapsulation layer 22 located on a side of the first inorganic encapsulation layer 21 away from the substrate 1, and the organic encapsulation layer 22 extends from the display region AA to the non-display region AB and fills the via holes 31.

The organic encapsulation layer 22 can further improve the encapsulation effect on the light-emitting sub-pixels, and the gas reaching the organic encapsulation layer 22 through the via holes 31 can also be discharged through the organic encapsulation layer 22.

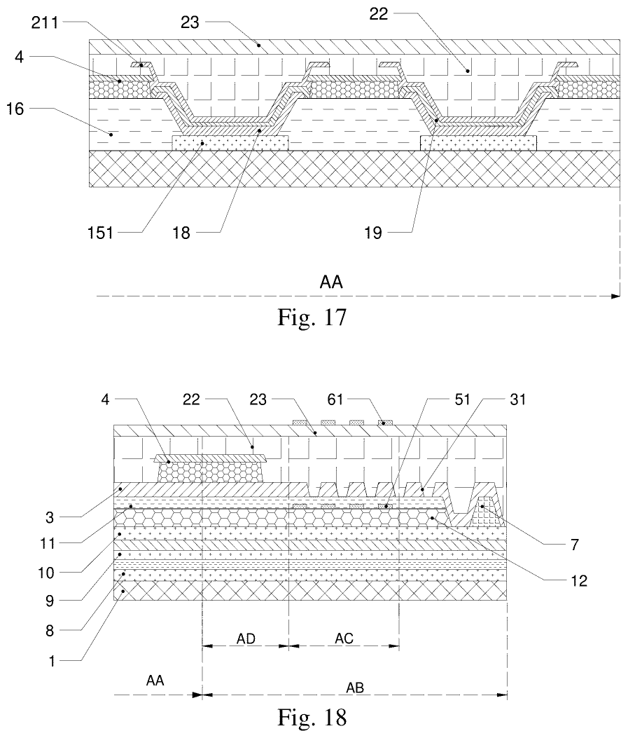

Optionally, referring to FIG. 17 and FIG. 18, the display panel further includes a second inorganic encapsulation layer 23 located on a side of the organic encapsulation layer 22 away from the substrate 1, and the second inorganic encapsulation layer 23 extends from the display region AA to the non-display region AB. The second inorganic encapsulation layer 23 can further improve the encapsulation effect on the light-emitting pixels.

In some optional embodiments, referring to FIG. 14 again, the isolation structure 4 includes a first isolation portion 41 and a second isolation portion 42 sequentially stacked in the direction away from the substrate 1, and an orthographic projection of the first isolation portion 41 on the substrate 1 is located within an orthographic projection of the second isolation portion 42 on the substrate 1.

Since the second isolation portion 42 is located on the side of the first isolation portion 41 away from the substrate 1, and a lateral width of the second isolation portion 42 is larger than a lateral width of the first isolation portion 41, the second isolation portion 42 may disconnect the light-emitting layer 18 with the second electrode layer at the isolation structure 4. Thus, it can facilitate that the isolation structure 4 formed by the first isolation portion 41 and the second isolation portion 42 can independently package each of the light-emitting pixels.

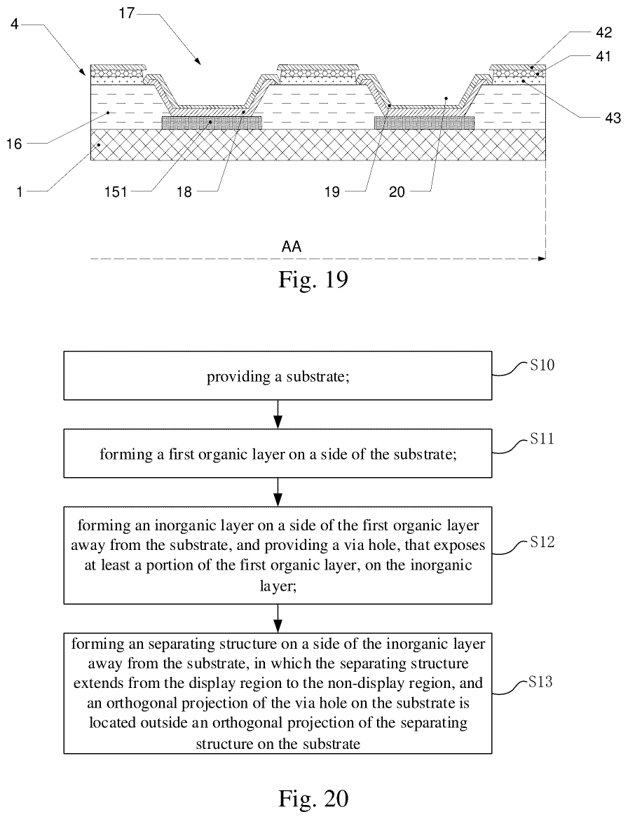

In some optional embodiments, referring to FIG. 14 again, the second electrode 19 is electrically connected to the first isolation portion 41; referring to FIG. 19, and/or the isolation structure 4 further includes a third isolation portion 43 located on a side of the first isolation portion 41 facing the substrate 1, and the second electrode 19 is electrically connected to the third isolation portion 43. A material of the third isolation portion 43 includes molybdenum metal; and/or a material of the first isolation portion 41 includes aluminum metal; and/or a material of the second isolation portion 42 includes titanium metal. Therefore, when the isolation structure 4 separates the second electrode layer into the second electrode 19, the second electrode 19 can be easier to electrically connect with the first isolation portion 41 or the third isolation portion 43.

In summary, in the present application, by providing the via holes 31, that exposes at least a portion of the first organic layer 2, on the inorganic layer 3, the paths of discharging the gas inside the screen body can be arranged on the inorganic layer 3, which can facilitate discharging the gas inside the screen body, and improve the reliability of the display panel.

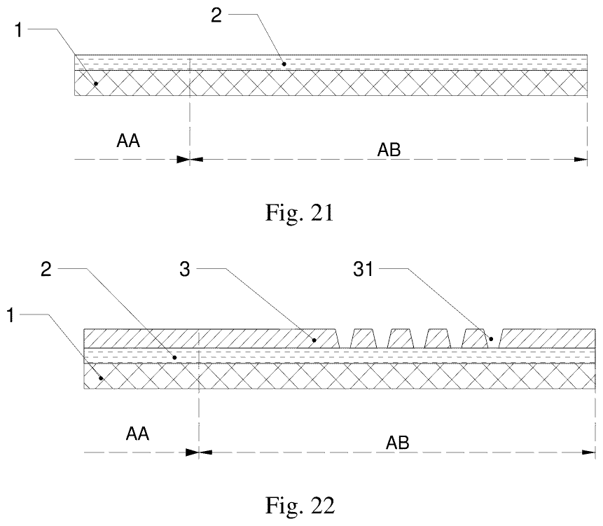

In some optional embodiments, referring to FIG. 20, the present application further provides a method of manufacturing a display panel, the display panel includes a display region AA and a non-display region AB, the non-display region AB includes a first border region 25, and the method includes:
S10: providing a substrate 1;
S11: forming a first organic layer 2 on a side of the substrate 1;
referring to FIG. 21, forming the first organic layer 2 on the side of the substrate 1;
S12: forming an inorganic layer 3 on a side of the first organic layer 2 away from the substrate 1, and providing a via hole 31, that exposes at least a portion of the first organic layer 2 and is located within the first border region 25, on the inorganic layer 3;
referring to FIG. 22, after forming the inorganic layer 3 on the side of the first organic layer 2 away from the substrate 1, providing the via hole 31, that exposes at least a portion of the first organic layer 2, on the inorganic layer 3 by means of exposure and development;
S13: forming a isolation structure 4 on a side of the inorganic layer 3 away from the substrate 1, in which the isolation structure 4 extends from the display region AA to the non-display region AB, and an orthographic projection of the via hole 31 on the substrate 1 is located outside an orthographic projection of the isolation structure 4 on the substrate 1.

The gas generated in the film layer of the screen can be transferred in the first organic layer 2 and reach to the via holes 31. Since the orthographic projections of the via holes 31 on the substrate 1 are located outside the orthographic projection of the isolation structure 4 on the substrate 1, the isolation structure 4 cannot block the gas from being discharged through the via holes 31. Thus, the display panel has the paths of discharging the gas, so that it is easier to discharge the gas inside the screen body. After the reliability testing, the encapsulation failure is not easy to occur, and the reliability of the display panel can be improved.

In some optional embodiments, the present application further provides an electronic device including the display panel as described in the present application. The electronic device may include a device with the image processing capability, such as a server, a personal computer or a laptop. Since the electronic device includes the display panel as described in the present application, the reliability of the electronic device is relatively high.

The various technical features in the above embodiments can be combined arbitrarily. In order to make the description concise, only a portion of the possible combinations of the various technical features in the above embodiments have been described. However, as long as the combinations of the technical features have no contradiction, they should be considered within the scope of the present specification.

The embodiments as described above merely express several embodiments of the present application, which are described more specifically and detailedly, but cannot be understood as a limitation on the scope of the present application. It should be noted that, for those skilled in the art, several modifications and improvements can be made without departing from the concept of the present application, all of which fall within the scope of the present application. Therefore, the scope of the present application should be based on the claims.

What is claimed is:

1. A display panel, comprising a display region and a non-display region, the non-display region comprising a first border region, and the display panel comprising:
a substrate;
a first organic layer, located on a side of the substrate;
an inorganic layer, located on a side of the first organic layer away from the substrate, and provided with a via hole exposing at least a portion of the first organic layer and located within the first border region; and
a isolation structure, located on a side of the inorganic layer away from the substrate and extending from the display region to the non-display region, wherein an orthographic projection of the via hole on the substrate is located outside an orthographic projection of the isolation structure on the substrate.

2. The display panel according to claim 1, wherein the inorganic layer is provided with a plurality of via holes.

3. The display panel according to claim 2, wherein the plurality of via holes are provided uniformly.

4. The display panel according to claim 2, wherein the first border region comprises a first border sub-region and a second border sub-region located on two sides of the display region, respectively, and arranged opposite to each other in a first direction;
the display panel further comprises a scan line, and the first direction is a direction in which the scan line extends within the display region.

5. The display panel according to claim 2, wherein orthographic projections of the via holes on the substrate are located on a side of the orthographic projection of the isolation structure on the substrate away from the display region; and
the non-display region at least partially surrounds the display region.

6. The display panel according to claim 2, wherein the display panel further comprises a dam structure located within the non-display region, the non-display region further comprises a shielding region, and the dam structure is located on a side of the shielding region away from the display region.

7. The display panel according to claim 6, wherein a density of the via holes located within the shielding region is lower than a density of the via holes located within a region close to the dam structure.

8. The display panel according to claim 6, wherein the via holes are arranged uniformly in a direction from a side of the shielding region close to the dam structure to the dam structure.

9. The display panel according to claim 6, wherein a density of the via holes gradually increases in a direction from the shielding region to the dam structure.

10. The display panel according to claim 6, wherein a diameter of each of the via holes located within the shielding region is smaller than a diameter of each of the via holes located within the region close to the dam structure; and
diameters of the via holes gradually increase in a direction from the shielding region to the dam structure.

11. The display panel according to claim 6, wherein a distance between two adjacent via holes located within the shielding region is larger than a distance between two adjacent via holes within the region close to the dam structure; and
distances between adjacent via holes gradually decrease in a direction from the shielding region to the dam structure.

12. The display panel according to claim 6, comprising a shielding layer, wherein the shielding layer is arranged on a side of the inorganic layer close to the substrate and within the shielding region, the shielding layer comprises a plurality of shielding lines, the display panel further comprises a touch layer located on a side of the isolation structure away from the substrate, the touch layer comprises a plurality of touch electrodes, and orthographic projections of the touch electrodes on the substrate at least partially overlap with orthographic projections of the shielding lines on the substrate.

13. The display panel according to claim 12, wherein orthographic projections of the via holes on the substrate are located outside the orthographic projections of the shielding lines on the substrate; and
in the shielding region, the orthographic projection of each of the via holes on the substrate is located between orthographic projections of two adjacent shielding lines on the substrate.

14. The display panel according to claim 13, wherein the display panel comprises a first metal layer, a second metal layer, a third metal layer and a fourth metal layer sequentially stacked in a direction away from the substrate, and the fourth metal layer comprises the shielding layer;
the display panel further comprises a second organic layer located on a side of the shielding layer close to the substrate;
the display panel further comprises a first planarization layer located between the third metal layer and the fourth metal layer, and the second organic layer comprises the first planarization layer; and
the display panel further comprises a second planarization layer located on a side of the fourth metal layer away from the substrate, and the first organic layer comprises the second planarization layer.

15. The display panel according to claim 13, wherein the display panel comprises a first metal layer, a second metal layer, a third metal layer, a fourth metal layer and a first electrode layer sequentially arranged in a direction away from the substrate, and the first electrode layer comprises the shielding layer;
the first electrode layer is located between the first organic layer and the inorganic layer; and
the first electrode layer comprises a first electrode, and the first electrode comprises an anode.

16. The display panel according to claim 6, wherein the non-display region further comprises a driving circuit region located between the display region and the shielding region, and the driving circuit region is provided with a driving circuit line.

17. The display panel according to claim 1, wherein the display panel further comprises a first electrode layer, a light-emitting layer and a second electrode layer sequentially stacked in a direction away from the substrate, the first electrode layer comprises a first electrode, the second electrode layer comprises a second electrode, the isolation structure is provided with an isolation opening, the isolation opening is located within the display region, and the second electrode is located within the isolation opening and electrically connected to the isolation structure;
in the display region, an orthographic projection of the isolation structure on the substrate is in a mesh-shaped structure; and
the light-emitting layer comprises a light-emitting part, and the light-emitting part is located within the isolation opening.

18. The display panel according to claim 17, wherein the display panel further comprises a pixel-defining layer located on a side of the first electrode layer away from the substrate, the pixel-defining layer comprises a plurality of pixel openings, the pixel openings expose the first electrode, the orthographic projection of the isolation structure on the substrate is located between orthographic projections of two adjacent pixel openings on the substrate, and orthographic projections of the pixel openings on the substrate are located within a orthographic projection of the isolation opening on the substrate; and
the inorganic layer comprises the pixel-defining layer.

19. The display panel according to claim 17, wherein the display panel further comprises a first inorganic encapsulation layer located on a side of the second electrode layer away from the substrate, the first inorganic encapsulation layer comprises a plurality of encapsulation units, and the encapsulation units extend from a side face of the isolation structure onto a side of the isolation structure away from the substrate;
the display panel further comprises an organic encapsulation layer located on a side of the first inorganic encapsulation layer away from the substrate, and the organic encapsulation layer extends from the display region to the non-display region and fills the via holes; and
the display panel further comprises a second inorganic encapsulation layer located on a side of the organic encapsulation layer away from the substrate, and the second inorganic encapsulation layer extends from the display region to the non-display region.

20. The display panel according to claim 17, wherein the isolation structure comprises a first isolation portion and a second isolation portion sequentially stacked in the direction away from the substrate, and an orthographic projection of the first isolation portion on the substrate is located within an orthographic projection of the second isolation portion on the substrate.

21. The display panel according to claim 20, wherein the second electrode is electrically connected to the first isolation portion; the isolation structure further comprises a third isolation portion located on a side of the first isolation portion facing the substrate, and the second electrode is electrically connected to the third isolation portion.

22. A method for manufacturing a display panel, wherein the display panel comprises a display region and a non-display region, the non-display region comprises a first border region, and the method comprises:
providing a substrate;
forming a first organic layer on a side of the substrate;
forming an inorganic layer on a side of the first organic layer away from the substrate, and providing a via hole, exposing at least a portion of the first organic layer and located within the first border region, on the inorganic layer; and
forming an isolation structure on a side of the inorganic layer away from the substrate, wherein the isolation structure extends from the display region to the non-display region, and an orthographic projection of the via hole on the substrate is located outside an orthographic projection of the isolation structure on the substrate.

23. An electronic device, comprising the display panel according to claim 1.
